(19) United States
(12) Patent Application Publication
(10) Pub. No.: US 2013/0048076 A1
(43) Pub. Date: Feb. 28, 2013

(54) DYE-SENSITIZED SOLAR CELL

(71) Applicants: Kazuya ISOBE, Tokyo (JP); Kenichi ONAKA, Tokyo (JP)

(72) Inventors: Kazuya ISOBE, Tokyo (JP); Kenichi ONAKA, Tokyo (JP)

(73) Assignee: KONICA MINOLTA BUSINESS TECHNOLOGIES, INC., Tokyo (JP)

(21) Appl. No.: 13/569,912

(22) Filed: Aug. 8, 2012

(30) Foreign Application Priority Data
Aug. 24, 2011 (JP) 2011-182329

(51) Int. Cl. H01L 51/46

(52) U.S. Cl. 136/263

(57) ABSTRACT

In the present invention, a dye-sensitizing solar cell with which high open voltage (Voc) and high short-circuit current (Jsc) are obtained is provided even though a conductive polymer is used as a hole transport material, whereby high photoelectric conversion efficiency can be obtained. Disclosed is a dye-sensitized solar cell comprising a substrate, a first electrode, a photoelectric conversion layer comprising a semiconductor and a sensitizing dye, a hole transport layer comprising a solid stale hole transport material, and a second electrode, wherein the solid state hole transport material contained in the hole transport layer comprises a conductive polymer formed by polymerizing a compound having a thiophene structure, and the hole transport layer has an ionization potential of 5.0-5.5 eV.

This application claims priority from Japanese Patent Application No. 2011-182329 filed on Aug. 24, 2011, which is incorporated hereinto by reference.

### TECHNICAL FIELD

The present invention relates to a photoelectric conversion element having a function to convert light energy into electrical energy, and specifically to a dye-sensitized solar cell in which a solid material is used as a hole transport material.

### BACKGROUND

The photoelectric conversion element typified by a solar cell is an element with which light energy is converted into electrical energy to supply electric power into each of various apparatuses, and development of the photoelectric conversion element in which an inorganic system material typified by silicon is used has been studied. Examples of the inorganic system material include single-crystal silicon, amorphous silicon, indium selenide and so forth, but in the case of the photoelectric conversion element in which an inorganic system material is used, a purification step by which a high purity inorganic system material is formed, and another manufacturing step by which a multilayer p-n junction structure is prepared are necessary to be carried out, whereby there has appeared a problem in productivity. Further, since rare metal such as indium or the like is utilized, there has also appeared a problem with respect to a stable supply system of raw material.

(Introduction of Organic Photoelectric Conversion Element)

On the other hand, a photoelectric conversion element in which an organic material capable of stable supply via synthesis has been studied, and for example, known has been an organic photoelectric conversion element in which an electron-conductive (n-type) perylenetetracarboxyiic acid and hole-conductive (p-type) copper phthalocyanine are jointed. In the case of such an organic photoelectric conversion element, it was found out that an exiton diffusion length and a space-charge layer were desired to be improved, and in response to this, proposed was a method in which photoelectric conversion was designed to be efficiently conduced by increasing area in the p-n junction section composed of an n-type organic material and a p-type organic material. Specifically disclosed was a technique in which photoelectric conversion was conducted all over the film by using an n-type electron-conductive material in complex with a p-type hole-conductive polymer in the film to increase the p-n junction section. Further, also disclosed was a technique by which a conjugated polymer as a hole-conductive polymer was used in complex with fullerene as an electron-conductive material.

(Introduction of Dye-Sensitized Photoelectric Conversion Element)

Incidentally, since the above-described organic photoelectric conversion element has a photoelectric conversion efficiency lower than that of one made of an inorganic material, improvement of the photoelectric conversion efficiency has been studied, and attention has been focused on a technique of a dye-sensitized photoelectric conversion element to solve the foregoing drawback. Specifically, proposed has been a technique intended to improve the photoelectric conversion efficiency when an adsorption amount of an organic sensitizing dye is increased to increase the semiconductor surface employing porous titanium oxide (refer to Non-Patent Document 1, for example). In this technology, an organic sensitizing dye having been adsorbed on the surface of porous titanium oxide is optically excited, and electrons are injected into the titanium oxide from the dye to form dye cation. Then, in the element, the cycle of donation and acceptance of electrons is repeated from the counter electrode via a hole transport layer having an electrolytic solution in which an iodine-containing elecrolyte is dissolved in an organic solvent because of presence of the foregoing dye cation to realize improvement of the photoelectric conversion efficiency. Further, in the case of this technology, titanium oxide used for a semiconductor is not one refined in high purity, and the photoelectrically convertible visible range is expanded to enhance possibility of a dye-sensitized photoelectric conversion element. On the other hand, an electrolyte was used in a hole transport layer, attention should have been paid to avoidance of dissipation of chemical species caused by liquid leakage.

(Problematic Point and Introduction of a Dye-Sensitized Photoelectric Conversion Element in which Solid Hole Transport Material is used)

With respect to this problem, proposed has been a technique concerning all solid state dye-sensitized photoelectric conversion element in which a solid material such as an amorphous organic hole material, copper iodide or the like is used as a hole transport material (refer to Non-Patent Documents 2 and 3, for example). Among solid hole transport materials, there has appeared and studied a conductive polymer typified by PEDOT (polyethylene dioxythiophene) as one of those in which a high photoelectric conversion efficiency is expected to be obtained because of a structure thereof (refer to Patent Documents 1 and 2, and Non-Patent Document 4, for example).

For example, in Patent Document 1, disclosed is a technique by which polythiophene or the like as one of conductive polymers is used as a hole transport material, and a hole transport layer is formed on a layer containing semiconductor particles each to which a dye is adsorbed. Further in Patent Document 2, disclosed is a technique by which a coating solution containing polyethylene dioxythiophene as one of polythiophenes is coated on the first electrode to prepare a solar cell unit.

### PATENT DOCUMENT

(Patent Document 1) Japanese Patent O.P.I. (Open to Public inspection) Publication No. 2000-106223

(Patent Document 2) Japanese Patent O.P.I. Publication No. 2011-009419

### NON-PATENT DOCUMENT

(Non-Patent Document 1) B. O'Regan, M. Gratzel, Nature, 353, 737 (1991)

(Non-Patent Document 2) U. Bach, D. Lupo, P. Comte, J. E. Moser, F, Weissortel, J. Salbeck, H. Spreitzer and M. Grated, Nature, 395, 583 (1998)

(Non-Patent Document 3) Akinori KONNO, Gamaralalage R. A. Kumara, Ryosuke HARA and Kirthi TENNAKONE: Electrochemistry 432, 70 No. 6 (2002)

(Non-Patent Document 4) J. Xia, N. Masaki, M. Lira-Cantu, Y, Kim, K. Jiang and S. Yanagida: Journal of the American Chemical Society, 130, 1258 (2008)

### SUMMARY

As described above, development of a dye-sensitized solar cell (photoelectric conversion element) in which a conductive polymer is used as a hole transport material has been studied, but it is found out that when the studies are gradually in progress, a high level of photoelectric conversion efficiency is not necessarily obtained, even though using a conductive polymer. That is, when a conductive polymer is used as a hole transport material, an energy level in the ground state is shifted on the positive side in comparison to an energy level of the redox couple used in a liquid electrolyte, whereby open voltage (Voc) is to be obtained, but roughly the same level of Voc as in the case where the liquid electrolyte is used remains unchanged. Further, as to contact with a sensitizing dye, it is also found out that no sufficient area can be obtained, compared with the case where a liquid electrode is used as a hole transport material, and there appears a problem such that short-circuit current (Jsc) is low.

The present invention was made on the basis of the above-described problem, and it is an objective to provide a dye-sensitizing solar cell with which high open voltage (Voc) and high short-circuit current (Jsc) are obtained even though a conductive polymer is used as a hole transport material, whereby high photoelectric conversion efficiency can be obtained.

### BRIEF DESCRIPTION OF THE DRAWINGS

Embodiments will now be described, by way of example only, with reference to the accompanying drawings which are meant to be exemplary, not limiting, and wherein like elements numbered alike in several figures, in which:

FIG. 1 is a schematic cross-sectional view showing an example of a dye-sensitized solar cell of the present invention.

FIGS. 2a and 2b each show the relationship between the numerical value of “form factor FF” and shape of “voltage-current characteristic graph”,

### DESCRIPTION OF THE PREFERRED EMBODIMENTS

After considerable effort during intensive studies on the basis of the above-described situation, the studies including experiments have been done by the inventors. That is, it should be satisfied in order to obtain high open voltage (Voc) and high short-circuit current (Jsc) that an energy level of a hole transport layer formed of a comparative polymer is surely elevated, and an injection barrier of holes from a sensitizing dye in a photoelectric conversion layer to a hole transport layer is lowered. When a layer structure capable of achieving the foregoing via introduction of dye-sensitizing solar cells possessing the following structures.

That is, the above-described problem can be solved by the dye-sensitized solar cells possessing the following structures.

(Structure 1) A dye-sensitized solar cell comprising a first electrode and provided thereon, a photoelectric conversion layer comprising a semiconductor and a sensitizing dye, a hole transport layer comprising a solid state hole transport material and a second electrode in this order, wherein the solid state hole transport material contained in the hole transport layer comprises a conductive polymer formed by polymerizing a compound having a structure represented by the following Formula (1), and the hole transport layer has an ionization potential of 5.0-5.5 eV:

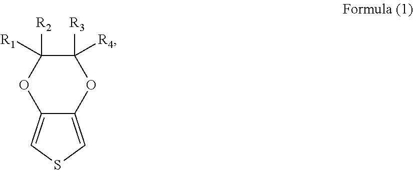

where each of R₁, R₂, R₃ and R₄ represents a hydrogen atom, a halogen atom, an alkyl group, a cycloalkyl group, an alkoxy group, an aryl group, or an alkyl group comprising an oxyethylene group, and R₁, R₂, R₃ and R₄ may be identical to each other, or may be different from each other.

(Structure 2) The dye-sensitized solar cell of Structure 1, wherein at least one of R₁, R₂, R₃ and R₄ in the compound having a structure represented by Formula (1) comprises an alkyl group having 3-14 carbon atoms, or an alkyl group comprising an oxyethylene group.

(Structure 3) The dye-sensitized solar cell of Structure 1 or 2, wherein the hole transport layer is formed during electropolymerization.

(Structure 4) The dye-sensitized solar cell of Structure 3, wherein a solvent used during the electropolymerization is a mixed solvent comprising a solvent having a dielectric constant of 50 or more.

(Structure 5) The dye-sensitized solar cell of Structure 3 or 4, wherein an electrolytic solution used during the electropolymerization comprises a compound represented by Formula (1) and a supporting electrolyte, and the supporting electrolyte has 2.5-50 times larger molar concentration than that of the compound represented by Formula (1).

While the preferred embodiments of the present invention have been described using specific terms, such description is for illustrative purposes only, and it is to be understood that changes and variations may be made without departing from the spirit or scope of the appended claims.

### DETAILED DESCRIPTION OF THE INVENTION

The present invention relates to a dye-sensitized solar cell in which a sensitizing dye is adsorbed onto a semiconductor surface, and specifically to a dye-sensitized solar cell (hereinafter, referred to also as a photoelectric conversion element) in which a conductive polymer is used as a hole transport material.

Next, the present invention will be described in detail. Incidentally, “a conductive polymer formed by polymerizing a compound having a structure represented by Formula (1)” described in the present invention means a polymer having a conjugation type main chain structure called a polyene structure in which a covalent bond and a single bond are alternately arranged to be situated. This polymer is one in which charge provided via addition of donors and acceptors moves the main chain of a π conjugate structure to generate conductivity. Further, “a conductive polymer formed by polymerizing a compound having a structure represented by Formula (1)” is specifically one having a heterocyclic structure in which a sulfur atom is contained in the main chain, and generally one called “polythiophene based polymer” or “polythiophenes”.

Further, a dye-sensitized solar cell of the present invention is one fitted with “a hole transport layer having an ionization potential of 5.0-5.5 eV”.

(Structure of Dye-Sensitized Solar Cell)

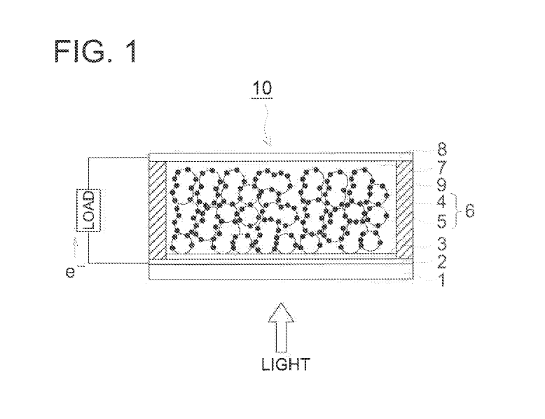

First, a structure of a dye-sensitized solar cell of the present invention will be described referring to FIG. 1. FIG. 1 is a schematic cross-sectional view showing an example of a dye-sensitized solar cell of the present invention.

As shown in FIG. 1, dye-sensiiized solar cell 10 is composed of substrate 1, first electrode 2, photoelectric conversion layer 6, hole transport layer 7, second electrode 8, partition wall 9 and so forth. Photoelectric conversion layer 6 contains semiconductor 5 and sensitized dye 4. In order to prevent short-circuiting, barrier layer 3 is preferably provided between the first electrode 2 and photoelectric conversion layer 6. Solar light enters from the direction of an arrow indicated in the lower portion of the figure.

(Mechanism in which Current Flows with Dye-Sensitized Solar Cell)

Dye-sensitized solar cell 10 serves as a battery via photoelectric conversion through the following procedures. That is, (1) When the first electrode 2 is exposed to light, sensitizing dye contained in photoelectric conversion layer 6 absorbs light to release electrons. In this case, the sensitizing dye becomes an oxide. (2) Electrons released from the sensitizing dye move to a semiconductor in photoelectric conversion layer 6, and further, move to the first electrode 2 from the semiconductor. (3) Electrons transferred to the first electrode 2 come around to the second electrode 8 as a counter electrode to reduce a hole transport material with the second electrode. (4) The foregoing sensitizing dye oxide receives electrons from the reduced hole transport material, and returns to the original state (sensitizing dye). (5) When (1), (2), (3) and (4) described above are repeated, electron transfer from the first electrode 2 to the second electrode 8 is repeated to extract electrons.

Thus, in the case of dye-sensitized solar cell 10 in FIG. 1 the sensitizing dye is to be excited via exposure to light to release electrons, and the released electrons flow to the outside after their reaching the first electrode 2 via the semiconductor. On the other hand, electrons move to serve as a battery in such a way that the sensitizing dye which has become an oxide via release of electrons receives elections supplied from the second electrode 8, from the hole transport layer to return to the original state.

Dye-sensitized solar cell 10 of the present invention is one fitted with “a hole transport layer having an ionization potential of 5.0-5.5 eV”. The hole transport layer contains a conductive polymer as a solid state hole transport material constituting a dye-sensitized solar cell of the present invention will be described below.

(Explanation of Hole Transport Layer)

First, a hole transport layer in which “conductive polymer” as a solid material is contained as a hole transport material will be described. Holes are moved toward the second electrode 8 from an excited sensitizing dye when hole transport layer 7 in dye-sensitized solar cell 10 as shown in FIG. 1 absorbs light to release electrons. In other words, as previously described, hole transport layer 7 receives electrons from the second electrode 8, and received electrons are put into a sensitizing dye in photoelectric conversion layer 6, which has been excited, to return to bring the sensitizing dye back to the state before exposure to light.

(Advantage to use Conductive Polymer as Hole Transport Material)

In the present invention, since the after-mentioned conductive polymer is used as a hole transport material, liquid leakage feared in a dye-sensitized solar cell in which an electrolytic solution is used as a hole transport material does not occur. Further, since a conductive polymer in which electrons are structurally easy to be moved is used as a hole transparent material, it would appear that donation and acceptance of electrons from the second electrode to a sensitizing dye in an excited state are stably conducted in a hole transport layer to possibly generate a high photoelectric conversion efficiency. In the present invention, it would appear that the photoelectric conversion, efficiency can be improved by controlling ionization potential to fall within a suitable range, employing a conductive polymer formed by polymerizing a compound represented by the after-mentioned Formula (1).

(Concrete Explanation of Conductive Polymer)

A conductive polymer formed by polymerizing a compound having a structure represented by the following Formula (1) belongs to polymers called polythiophenes each having a heterocyclic structure containing a sulfur atom (sulfur-containing heterocyclic structure) in the main chain. Among the polythiophenes, the polymer formed by polymerizing a compound having a structure represented by the following Formula (1) is one having a side chain structure (ethylene dioxy unit) in addition to a conjugation type main chain structure in which a covalent bond and a single bond are alternately arranged to be situated, which is contributed to charge movement.

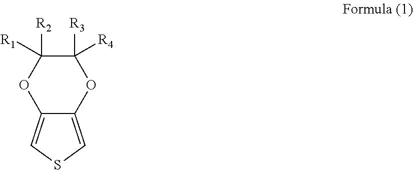

Of these, each of R₁, R₂, R₃ and R₄ in the structure represented by the above-described Formula (1) represents a hydrogen atom, a halogen atom, an alkyl group, a cycloalkyl group, an alkoxy group, an aryl group, or an alkyl group possessing an oxyethylene group.

Examples of halogen atoms represented by R₁, R₂, R₃ and R₄ in the structure represented by the above-described Formula (1) include a chlorine atom, a bromine atom, a fluorine atom and so forth. Further, examples of the alkyl group include a methyl group, an ethyl group, a propyl group, an isopropyl group, a tert-butyl group, a pentyl group, a hexyl group, an octyl group, a dodecyl group, a tridecyl group, a tetradecyl group, a pentadecyl group and so forth. Further, examples of the cycloalkyl group include a cyclopentyl group, a cyclohexyl group and so forth. Examples of the alkoxy group include a methoxy group, an ethoxy group, a propoxy group, a butoxy group and so forth. Examples of the aryl group include a phenyl group, a naphthyl group, anthracenyl and so forth. An alkyl group possessing an oxyethylene group such as a methoxyethoxy group, a methoxyethoxyethoxy group or the like can be also exemplified.

Specific examples of the compound represented by the above-described Formula (1) are shown below, but compounds each represented by Formula (1) usable in the present invention are not limited to those shown below.

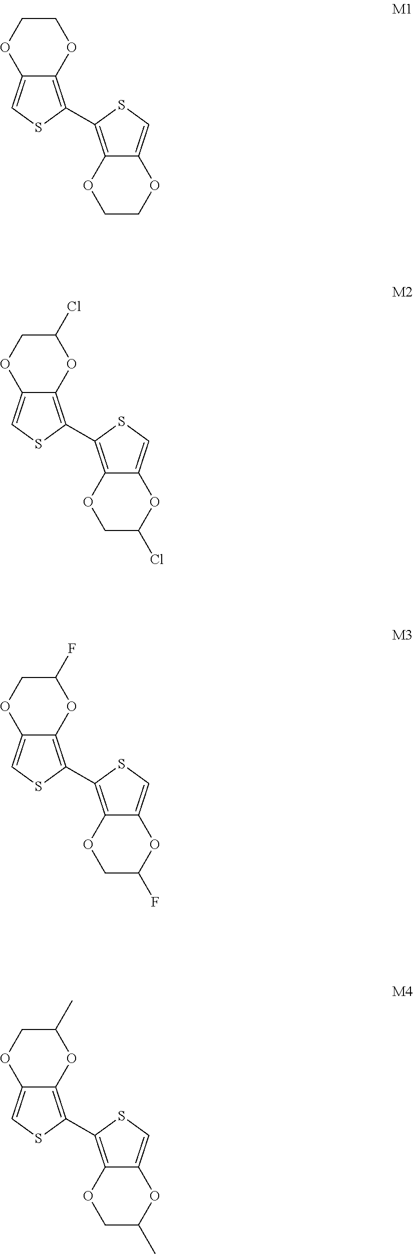 [SMILES: c1sc(-c2scc3c2OCCO3)c2c1OCCO2 ; ClC1COc2c(csc2-c2scc3c2OC(Cl)CO3)O1 ; FC1COc2c(csc2-c2scc3c2OC(F)CO3)O1 ; CC1COc2c(csc2-c2scc3c2OC(C)CO3)O1]

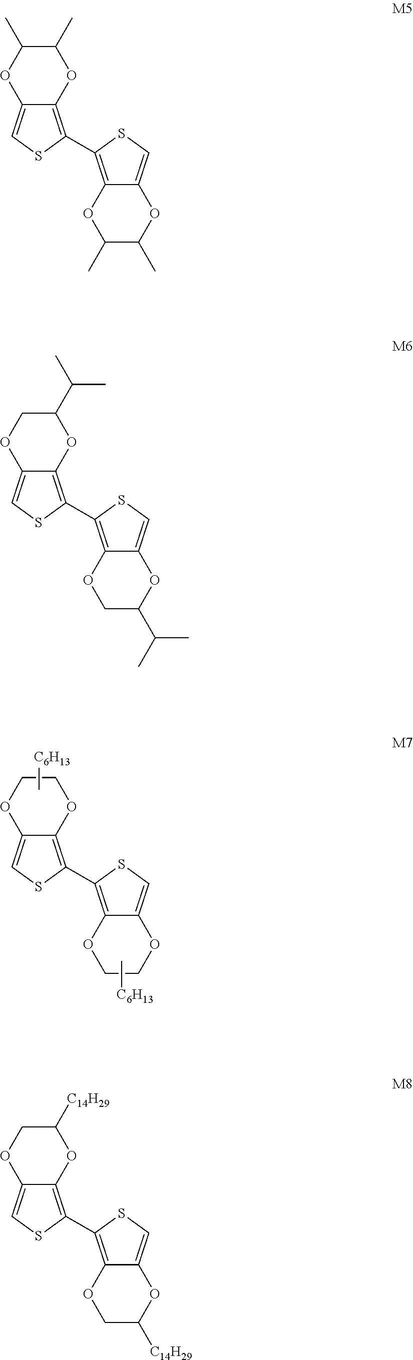

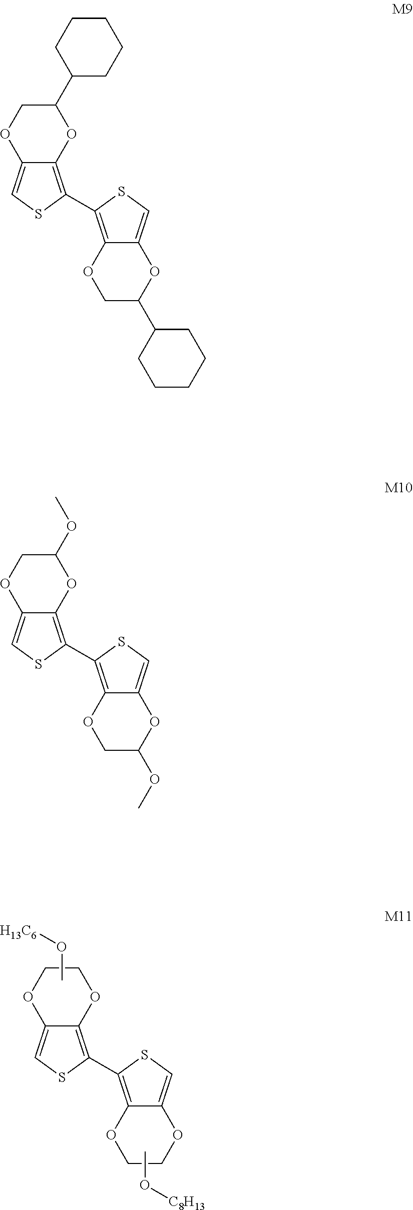

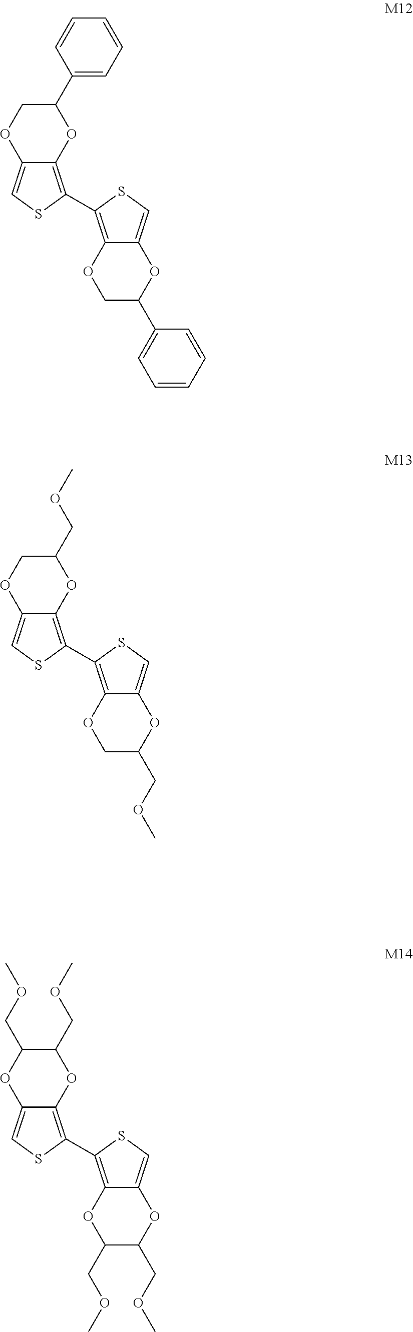 [SMILES: c1ccc(C2COc3c(csc3-c3scc4c3OC(c3ccccc3)CO4)O2)cc1 ; COCC1COc2c(csc2-c2scc3c2OC(COC)CO3)O1 ; COCC1Oc2csc(-c3scc4c3OC(COC)C(COC)O4)c2OC1COC]

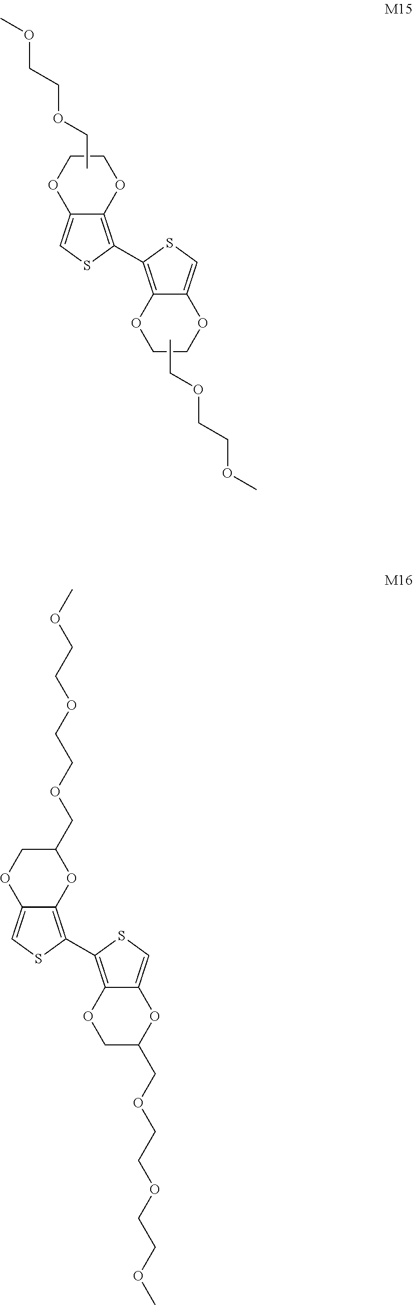

In the present invention, among compounds each represented by the above-described Formula (1) to form each of conductive polymers called polythiopenes, compounds each having the following substituent is preferably used.

(Advantage of Polythiophene with Limitation of Substituent in Claim 2)

At least one of R₁, R₂, R₃ and R₄ in a compound having a structure represented by the above-described Formula (1) is an alkyl group having 3-14 carbon atoms, or an alkyl group possessing an oxyethylene group having 3-14 carbon atoms.

A dye-sensitized solar cell in which a conductive polymer having been formed employing each of these desirably usable compounds is used as a hole transport material tends to obtain high Jsc, as confirmed from the after-mentioned results in Examples. It would appear that when a substituent serving as a steric barrier, which is capable of suppressing intermolecular interaction is present in the side chain, the formed conductive polymer is difficult to form regular molecular arrangement, whereby it becomes more amorphous. Thus, it would appear that the conductive polymer becomes easy to be diffused in pores of the porous semiconductor layer onto which the sensitizing dye is adsorbed, whereby contact with the semiconductor is further improved, and as a result, high Jsc is to be obtained.

Examples of a method of polymerizing a compound represented, by the above-described formula (1) include commonly known methods such as a method disclosed in J. R. Reynolda et al.: Adv. Mater., 11, 1379 (1999), and so forth.

(Method of Forming Hole Transport Layer)

Further, a hole transport layer containing a conductive polymer as a solid state hole transport material having been formed by using a compound represented by Formula (1) described above is possible to be prepared. Specifically provided is a formation method of coating a coating solution onto a photoelectric conversion layer by a commonly known method after preparing the coating solution containing a polymer. Examples of the coating method used for formation of the hole transport layer include a dipping method, a liquid-dropping method, a doctor blade method, a spin coating method, a brush coating method, a spray coating method, a roll coater method and so forth. Further, as a solvent for a coating solution, usable is an organic solvent corresponding to a polar solvent or an aptotic solvent, for example. That is, examples of the polar solvent include tetrahydrofuran (THF), butylene oxide, chloroform, cyclohexanone, chlorobenzene, acetone, various alcohols and so forth. Further, examples of the aprotic solvent include dimethyl hormamide (DMF), acetonitril, dimethoxy ethane, dimethyl sulfoxide, hexamethylphosphoric triamide and so forth.

In addition to a formation method employing a coating solution containing a polymer, also provided is another method by which a solution containing a compound represented by Formula (1), a polymerization catalyst, a polymerization rate modifier and so forth is coated on a photoelectric conversion layer, or polymerisation reaction is conducted via immersion in the solution to form a hole transport layer. As to the condition of the polymerization reaction, when the polymerization reaction is conducted via heating in air, it is preferably carried out at a heat temperature of 25-120° C., and a heat duration of 1 minute to 24 hours, depending on kinds and content ratio of a polymerization catalyst, a compound represented by Formula (1), a polymerization rate modifier and so forth, thickness of the layer to be formed, and so forth.

Further, the hole transport layer can be formed on a layer containing semecondictor particles onto which a sensitizing dye is adsorbed. An electrolytic solution used during electropolymerization contains a compound represented by Formula (1), a supporting electrolyte and a solvent which are to be subjected to polymerization thereof, but an additive can be added therein, if desired. Usable examples of solvents employed for electropolymerization include general-purpose organic solvents each having a considerably wide potential window such as methylene chloride, propylene carbonate, acetonitrile and so forth, and they each are usable as a mixed solvent in which water or another organic solvent is added, if desired.

(Method of Adjusting Ionization Potential (I. P) of Hole Transport Layer)

In order to control ionization potential of a hole transport layer to fall within the range of the present invention, the state of dopant presence is desired to be evenly dispersed on the entire hole transport layer at high concentration.

In order to do this, a microscopic layer structure of polythiophene to determine a structure of the hole transport layer is uniformized, and the dopant should be evenly distributed on a polythiophene layer at high concentration.

In the case of the present invention, a structure of the polythiophene layer as described above can be achieved by the following manufacturing condition to adjust ionization potential of the hole transport layer to fall within the range of the present invention.

A polythiophene layer as a hole transport layer of the present invention is obtained via electropolymerization of a compound represented by the foregoing Formula (1). That is, the polythiophene layer is formed on a layer containing semiconductor particles each onto which a sensitizing dye is adsorbed. An electrolytic solution used during electropolymerization contains a compound represented by the foregoing Formula (1), a supporting electrolyte (dopant-supplying compound) and a solvent which are to be subjected to polymerization, but an additive may be added therein, if desired.

In order to adjust the hole transport layer of the present invention to an I. P of 5.0-5.5 eV, the following condition (a) and condition (b) should be satisfied under a polymerization condition of this electropolymerization. (a) To use a mixed solvent in which at least a solvent having a dielectric constant (ε) of 50 or more is contained in a solvent used for an electrolytic solution used during electropolymerization.

Preferable examples of the solvent having a dielectric constant (ε) of 50 or more include ethylene carbonate (89.6), propylene carbonate (64.4), succinonitrile (56.5) and so forth; examples of solvent species used in combination include tetrahydrofuran (THF) (7.6), chloroform (4.8), cyclohexane (18.3), chlorobenzene (5.6), acetone (20.7), toluene (2.4), various alcohols such as methanol (32.7), ethanol (24.6) and so forth, dimethylformiamide (DMF) (36.7), acetonitrile (37.5), dimethoxy ethane (7.2), dimethylsulfoxide (46.7), γ-butyrolactone (39.0) and so forth; and acetonitrile and γ-butyrolactone are specifically preferable.

As a dielectric constant value of the solvent relating to the present invention, used is the dielectric constant described in ORGANIC SOLVENTS 3^{RD} EDITION/WILEY-INTERSCIENCE and so forth.

When using a solvent having a high dielectric constant, an ionic dissociation degree of a supporting electrolyte serving as a dopant during electropolymerization becomes high, whereby it would possibly appear that a doping state can be more evenly formed. On the other hand, when using a solvent having a high dielectric constant singly, viscosity thereof tends to be high and it would also appear that in contrast, formation of the evenly doping state is inhibited since diffusion of ions is to be suppressed. High dielectiic constant and low viscosity can be supported at the same time by using a mixed solvent, whereby a evenly doping state is presumably formed. An ionization potential relating to the present invention is adjusted to be obtained by using a mixed solvent containing a solvent having a dielectric constant (ε) of 50 or more to adjust dielectric constant (εₜₒₜₐₗ) of this mixed solvent.

This mixed solvent preferably has a dielectric constant (εₜₒₜₐₗ) of 40-60. Dielectric constant (εₜₒₜₐₗ) of a mixed solvent is represented by the following equation.

εₜₒₜₐₗ=A1×B₁+A2×B2+. . .

each represent a solvent blending ratio (volume ratio). (b) To adjust a dopant concentration during electropolymerization of a hole transport layer so as to make the dopant concentration to fall within a given range at high value.

Doping is generated with anions in a supporting electrode at the same time when a uniform polythiophene layer is formed as a hole transport layer obtained under condition (a). In this case, concentration of a supporting electrolyte used during electropolymerization is preferably 2.5 to 50 times larger molar concentration than that of a thiophene compound represented by Formula (1), and more preferably 3.0 to 30 times larger molar concentration than that of a thiophene compound represented by Formula (1).

In the case of less than the lower limit of the above-described range, the ionization potential tends easily to be smaller than 5.0 eV, and when exceeding the upper limit of the range, the ionization potential becomes larger than 5.5 eV. In any of the foregoing cases, a photoelectric conversion efficiency drops.

That is, in the case of an ionization potential of smaller than 5.0 eV, high Voc can be obtained as previously described, whereby the efficiency remains low. On the other hand, in the case of an ionization potential of larger than 5.5 eV, an energy level at the ground state of a sensitizing dye should be designed to be higher, whereby there appears a problem such that a high absorption range can not be sufficiently obtained, since it becomes difficult to design the sensitizing dye, and a bandgap of the sensitizing dye is to be broadened.

Examples of the supporting electrolyte serving as a dopant include LiClO₄, (n-C₄H₉)₄NBF₄, (n-C₄H₉)₄NPF₄, p-toluene sulfonate, dodecylbenzene sulfonate and so forth.

In order to achieve ionization potential of the present invention, satisfied should be condition (a) as well as condition (b) during electropolymerization.

Incidentally, ionization potential means energy quantity required to remove one electron from a ground state of a material. The ionization potential of a hole transport layer can be obtained by directly measuring a hole transport layer as a film. In order to measure ionization, potential, after a sample in the atmosphere is exposed to UV rays dispersed with a monochromator while varying energy, the ionization potential can be obtained by determining energy at which photoelectrons start to be released by a photoelectric effect. As a measuring device, measurements can be made with a surface analyzer AC-1, AC-2, AC-3 or the like, manufactured by RIKEN KEIKI Co., Ltd

Conventionally, a technique by which a hole transparent layer made of polythiophene is formed via electropolymerization is commonly known in Patent Document 1. However, a technique to make ionization potential of a hole transport layer to fall within the range of the present invention at high value is not disclosed in this cited document, and even though additionally trying to track the technique disclosed in Patent Document 1, the ionization potential becomes smaller than its lower limit of the range of the present invention, resulting in insufficient achievement of a photoelectric conversion efficiency and so forth.

Next, layer constitution of a dye-sensitized solar cell other than a hole transport layer will be described in detail.

(Explanation of Each Layer in Dye-Sensitized Solar Cell)

A dye-sensitized solar cell shown in FIG. 1 will be further described.

(Explanation of Substrate)

Substrate 1 is placed on the side in the light incidence direction of dye-sensitized solar cell 10; provides strength for the dye-sensitized solar cell; and is formed of a transparent material such as glass, a transparent resin or the like in order to obtain an excellent photoelectric conversion efficiency.

Light transmittance of substrate 1 is not specifically limited, but substrate 1 preferably has a light transmittance of 10% or more; more preferably has a light transmittance of 50% or more; and still more preferably has a light transmittance of 80-100%. Herein, “light transmittance” is referred to as total light transmittance in the visible light wavelength range, which is measured in accordance with “Plastics—Determination of the total luminous transmittance of transparent materials” based on JIS K. 7361-1 (corresponding to ISO 13468-1).

Substrate 1 usable in the present invention is possible to be appropriately selected from the commonly known, and made of a transparent inorganic material such as quartz, glass or the like, or each transparent resin material commonly known as described below.

Examples of the transparent resin material include polyethylene terephthalate (PET), polyethylene naphthalate (PEN), polyphenylene sulfide (PPS), polyamide (Pl), polycarbonate (PC), polystylene (PS), polypropylene (PP), polybutylene terephthalate (PBT), trimethylene terephthalate, polybutylene naphthalate, polyamideimide, a cycloolefin polymer, a styrene butadiene copolymer and so forth. Of the above-described resin materials, polyethylene terephthalate (PET), polyethylene naphthalate (PEN), polyphenylene sulfide (PPS), polyamide (PI) and so forth each exhibiting flexibility are commonly available, and are preferable in view of preparation of flexible photoelectric conversion elements.

Further, thickness of substrate 1 is possible to be appropriately designed, depending on material, application and so forth. For example, in cases where the substrate is made of a hard material as a transport inorganic material such as glass or the like, it preferably has an average thickness of 0.1-1.5 mm, and more preferably has an average thickness of 0.8-1.2 mm, Further, also in cases where a transparent resin material is used, the same average thickness as that of the transport inorganic material may be designed, but when using a transparent resin material exhibiting flexibility, the average thickness is preferably 0.5-150 μm, and more preferably 10-75 μm.

(Explanation of the First Electrode)

Next the first electrode 2 is placed between substrate 1 and photoelectric conversion layer 6, and used is one preferably having a light-reachable ratio of 80% or more, and more preferably having a light-reachable ratio of 90% or more in order to efficiently supply light to photoelectric conversion layer 6.

The first electrode 2 is formed of a commonly known metal material or metal oxide. Specific examples of the metal material include platinum, gold, silver, copper, aluminum and so forth, but silver is preferable since those having been processed in the form which is easy to produce light transmittance are largely supplied. For example, a grid pattern film possessing an opening, a film in which particles or nanowires are dispersed, and so forth are largely provided. Further, specific examples of metal oxide include SnO₂, ZnO, CdO, CTO system, In₂O₃, CdIn₂O₄ and so forth, and one in which at least one kind of atoms selected from Sn, Sb, F and Al is doped in the above-described metal oxide is preferably used. Of these, one in which Sn is doped in In₂O₃, which is called ITO; one in which Sb is doped in SnO₂; and conductive metal oxide in which F is doped in SnO₂, which is called FTO are preferable, but FTO is specifically preferable in view of heat resistance.

Further, the first electrode 2 is possible to be placed on the foregoing substrate 1. One in which the first electrode 2 is provided on the substrate is called a conductive support, and the conductive support preferably has a thickness of 0.1-5 mm. Further, the conductive support preferably has a surface resistance of 50 Ω/cm² or less, and preferably has a surface resistance of 10 Ω/cm² or less.

(Explanation of Photoelectric Conversion Layer)

Next, photoelectric conversion layer 6 will be described. Dye-sensitized solar cell 10 shown in FIG. 1 possesses photoelectric conversion layer 6 to convert light energy such as solar light to electrical energy, which is adjacently placed to the first electrode 2. Photoelectric conversion layer 6 contains semiconductors to which a sensitizing dye is adsorbed and is a section where light passing through the foregoing first electrode 2 is received. Thus, donation and acceptance of electrons are conducted between the first electrode 2 and the photoelectric conversion layer.

Conversion of light energy to electrical energy in photoelectric conversion layer 6 is conducted in the following order. First, light passing through the first electrode 2 enters photoelectric conversion layer 6, and collides with semiconductors. Light colliding with semiconductors is diffusely reflected in airy direction and diffused in photoelectric conversion layer 6. The diffused light comes into contact with a sensitizing dye to generate electrons and holes, and generated electrons move toward the first electrode 2. Photoelectric conversion layer 6 converts light energy to electrical energy in such a mechanism.

Thickness of photoelectric conversion layer 6 is not specifically limited, but specifically, the photoelectric conversion layer preferably has a thickness of roughly 0.5-25 μm, and more preferably has a thickness of roughly 1-10 μm. In addition, photoelectric conversion layer 6 has almost the same thickness as that of the contained semiconductor, and the semiconductor in the form of a layer is preferably used in order to realize miniaturization of an element and reduction of manufacturing cost,

(Explanation of Semiconductor)

Usable examples of semiconductor 5 used in photoelectric conversion layer 6 include a single element such as silicon, germanium or the like, a compound possessing an atom belonging to Group 3 (Group 3A) to Group 5 (Group 5A) and Group 13 (Group 3B) to Group 15 (Group 5B) in the periodic table of the elements, metal chalcogenide, metal nitride and so forth. Herein, metal chalcogenide means a compound composed of a metal atom and an atom belonging to Group 16 (Group 6B) in the periodic table of the elements such as an oxygen atom, a sulfur atom or the like, which is called a chalcogen element, and corresponds to metal oxide, metal sulfide, metal selenide, metal telluride or the like.

Specific examples of metal chalcogenide are, for example, those described below.

(1) Examples of metal oxide as the metal chalcogenide include TiO, TiO₂, Ti₂O₃, SnO₂, Fe₂O₃, WO₃, ZnO, Nb₂O₅ and so forth.

(2) Examples of metal sulfide as the metal chalcogenide include CdS, ZnS, PbS, Bi₂S₃, CuInS₂ and so forth.

(3) Examples of metal selenide and metal, telluride as the metal chalcogenide include CdSe, PbSe, CuInSe₂, TiO₂, SnO₂, Fe₂O₃, WO₃, ZnO, Nb₂O₅, CdS and PbS are preferably used; of these, TiO₂ and Nb₂O₅ are more preferably used; and titanium dioxide TiO₂ are still more preferably used. Titanium dioxide exhibits high sensitivity in response to light in addition to excellent electron transportability, and titanium dioxide per se receives light to directly generate electrons, whereby a high photoelectric conversion efficiency can be specifically and preferably expected. Further, since titanium dioxide has a stable crystalline structure, degradation caused by aging is difficult to occur even though it is exposed to light under the extreme environment, and the predetermined performance is possible to be produced stably for a long duration.

Incidentally, the crystalline structure of titanium dioxide is classified into an anatase type and a rutile type, and as a semiconductor material for a solar cell, usable is any of those such as an anatase type crystalline structure as a main structure, a rutile type crystalline structure as a main structure, and a mixture of both of them as a main structure. Of these, titanium dioxide having an anatase type crystalline structure exhibits efficient electron transportability. Further, when one in which an anatase type and a rutile type are mixed is used, a mixing ratio of the anatase type to the rutile type is not specifically limited, anatase type: rutile type=95:5 to 5:95 is possible to be used, and anatase type: rutile type=80:20 to 20:80 is preferably used.

Further, as metal nitride usable as a semiconductor, Ti₃N₄, for example, is typically exemplified, and further, metal sulfur compounds such as GaP, INP and so forth and compounds such as GaAs and so forth are also usable as semiconductors.

As semiconductors to be used in photoelectric conversion layer 6, not only the above-described compounds are used singly, but also plural compounds are usable in combination. For example, one in which 20% by weight of TiO₂ are mixed in Ti₃O₄, and a composite of ZnO and SnO₂ disclosed in J. Chem. Soc. Chem. Commun., 15 (1999) and so forth are exemplified. Further, when metal oxide or metal sulfide, and a compound other than the foregoing oxide or sulfide are used in combination, a content of the compound is preferably set to 30% by weight or less.

Further, as semiconductors used in photoelectric conversion layer 6, one having been subjected to a surface treatment employing an organic base is possible to be used. As to the surface treatment for semiconductors, mainly provided is a method by which semiconductors are immersed in a liquid tank containing an organic base to conduct a surface treatment. When the organic base is liquid, the organic base is used as it is, and when the organic base is solid, a solution in which it is dissolved in an organic solvent is used. Examples of the organic base used for the surface treatment include diaryl amine, triaryl amine, pyridine, 4-t-butylpyridine, polyvinylpyridine, quinoline, amidine and so forth. Of these, pyridine, 4-t-butylpyridine and polyvinylpyridine are preferable.

Further, a semiconductor material preferably possesses plural micropores (fine pores) in its surface in order to improve a photoelectric conversion efficiency via acceleration of diffuse reflection and diffusion of light traveling via collision, and a high photoelectric conversion efficiency can be expected since the foregoing titanium dioxide possesses fine pores on its surface. Fine pores of a semiconductor material, for example, can be specified by a ratio of pore area occupied per unit area of a semiconductor particle surface, which is called porosity. That is, in the case of the semiconductor material having an appropriate porosity, the adsorption area of a sensitizing dye having been adsorbed to the outer surface of the semiconductor material and the inner surface of fine pores is increased with increase of the surface area caused by fine pores in addition to acceleration of diffuse reflection and diffusion of light, whereby a photoelectric conversion efficiency is further improved. The porosity of a semiconductor material is not specifically limited, but in the case of titanium dioxide, for example, the porosity is preferably 5-90%; more preferably 15-80%; and most preferably 25-70%.

(Description of Average Particle Diameter of Semiconductor Material)

Further, an average particle diameter of semiconductor 5 is not specifically limited, but usually, the average particle diameter is preferably 1 nm to 1 μm, and more preferably 5-50 nm. When making the average particle diameter of the semiconductor material to fall within the above-described range, evenness of the semiconductor material is easy to be improved when sol liquid is prepared, and the specific surface area of the semiconductor material is identically arranged through improvement of the evenness, resulting in contribution to improvement of a power generation efficiency since the sensitizing dye is adsorbed to each semiconductor material at the equivalent level.

Further, semiconductor 5 has a structure in which a photosensitizing dye is adsorbed thereto, but adsorption formed between a semiconductor material and a photosensitizing dye is realized via, for example, physical action such as intramolecular attraction force, electrostatic attraction force and so forth, or chemical bond such as covalent bond, coordinate bond and so forth. The photosensitizing dye generates electrons and holes via light reception, and practically converts light energy to electrical energy in photoelectric conversion layer 6. That is, in photoelectric conversion layer 6, the region where a photosensitizing dye is present serves as a light-receiving region to generate elections and holes, and as previously described, sensitizing dye 4 is adsorbed to the area along the outer surface of semiconductor 5 and the inner surface of pores. Then, electrons generated from sensitizing dye 4 move to semiconductor 5 bonded to sensitizing dye 4, and move toward the first electrode 2 from semiconductor 5.

(Explanation of Sensitizing Dye)

Sensitizing dye 4 is one carried to semiconductor 5 via a sensitizing treatment conducted by a commonly known method. A commonly known sensitizing dye usable in a dye-sensitized solar cell is possible to be used in the present invention. Examples of the sensitizing dye usable in die dye-sensitized solar cell include organic pigments, carbon based pigments, inorganic pigments, and organic or inorganic dyes, which are a conventionally known.

First, as organic pigments each as a sensitizing dye, provided are phthalocyanine based pigments, azo based pigments, anthraquinone based pigments, quinacridone based pigments and perylene based pigments.

(1) Examples of phthalocyanine based pigments include phthaiocyanine green, phthalocyanine blue and so forth.

(2) Examples of azo based pigment include fast yellow, disazo yellow, condensed azo yellow, benzimidazolone yellow, dinitroaniline orange, benzimidazolone orange, toluidine red, permanent cannine, permanent red, naphthol red, condensed azo red, benzimidazolone carmine, benzimidazolone brown and so forth.

(3) Examples of anthraquinone based pigments include anthrapyrimidine yellow, anthraquinonyl red and so forth.

(4) Examples of quinacridone based pigments include quinacridone magenta, quinacridone maroon, quinacridone scarlet, quinacridone red and so forth.

(5) Examples of perylene based pigments include perylene red, perylene maroon and so forth.

The following organic pigments in addition to the above-described organic pigments are also usable. That is, examples thereof include azomethine based pigments such as copper azomethine yellow and so forth; quinophthalone based pigments such as quinophthalone yellow and so forth; isoindoline based pigments such as isoindoline yellow and so forth; and nitroso based pigments such as nickel dioxime yellow and so forth; perinone based pigments such as perinone orange and so forth; pyrrolo pyrrole based pigments such as diketo pyrrolo pyrrole red and so forth; dioxazin based pigments such as dioxazin violet and so forth; and so on.

Further, examples of carbon based pigments include carbon black, lamp black, furnace black, ivory black, graphite, fullerene and so forth.

Further, specific examples of dyes each usable as a photosensitizing dye include metal complex dyes such as RuL₂Cl₂, RuL₂(CN)₂, ruthenium 535-bisTBA (produced by Solaronics Inc.), [Ru₂ (NCS)₂]₂H₂O and so forth. Herein, “L” in RuL₂Cl₂ and RuL₂(CN)₂ represents 2,2-bipyridine or its derivative. Further, in addition to the foregoing metal complex dyes, organic dyes such as cyan based dyes, azo based dyes and so forth; and organic dyes derived from natural products such as a hibiscus dye, a blackberry dye, a raspberry dye, a pomegranate juice dye, a chlorophyll dye and so forth are possible to be used.

Incidentally, specific explanation of a sensitizing treatment to semiconductor 5 with sensitizing dye 4 will be given later in the section of the after-mentioned “Formation of photoelectric conversion layer”.

(Explanation of the Second Electrode)

Next, the second electrode 8 will be described. The second electrode 8 adjacent to hole transport layer 7 is formed in the form of a layer (flat plate-shaped), and its average thickness is appropriately designed to be set, depending on material, application and so forth and is not specifically limited. The second electrode 8 is possible to be formed by using commonly known conducting material and semiconducting material. Examples of the conducting material include various ion conducting materials, metals such as aluminum, nickel, cobalt, platinum, silver, gold, copper, molybdenum, titanium, tantalum and so forth or alloys containing the foregoing elements, various carbon materials such as graphite and so forth, and so on. Further, examples of the semiconductor material include p type semiconductor materials such as triphenyldiamine (monomer, polymer or the like), polyaniline, polypyrrole, polythiophene and phthalocyanine compounds such as copper phthalocyanine, or their derivatives. The second electrode 8 is possible to be formed by using the conducting material and the semiconductor material singly, or in combination with at least two kinds thereof.

(Explanation of Barrier Layer)

Dye-sensitized solar cell 10 shown in FIG. 1 possesses barrier layer 3 between the first electrode 2 and photoelectric conversion layer 6, and barrier layer 3 is placed to prevent generation of short-circuiting. In cases where barrier layer 3 is provided, the barrier layer has a thickness of roughly 0.01-10 μm, and is formed by using commonly known metal oxide or the like such as zinc oxide and so forth.

Next, a manufacturing method of the dye-sensitized solar cell will be described.

(Manufacturing Method of Dye-Sensitized Solar Cell)

The manufacturing method of the dye-sensitized solar cell relating to the present invention as an example will be described. The dye-sensitized solar cell relating to the present invention is possible to be prepared through the following procedures. The manufacturing method of the dye-sensitized solar cell relating to the present invention is not limited to those prepared through the following procedures, and the dye-sensitized solar cell relating to the present invention is also possible to be prepared by another known method.

[1] Formation of the First Electrode

Employing a substrate having a uniform thickness, which is made of transparent glass or a transparent resin exhibiting excellent heat resistance is provided, the first electrode 2 is formed on the substrate by a pulse laser evaporation method or the like with a commonly known film-forming apparatus. In addition, as an organic material exhibiting heat resistance, for example, a polyethylene naphthalate (PEN) resin, a polyimide resin and so forth are exemplified.

[2] Formation of Photoelectric Conversion Layer

Next, photoelectric conversion layer 6 is formed on the upper surface of the first electrode by using a semiconductor material. For example, photoelectric conversion layer 6 is possible to be formed by coating or spraying semiconductor onto a substrate on which the first electrode is formed in the case of particle-shaped semiconductors, for example, In the case of a semiconductor in the form of a film, it is possible to attach the semiconductor onto a substrate on which the first electrode is formed. As a preferred embodiment at a time when photoelectric conversion layer 6 is formed, provided is a method by which semiconductor particles are calcined to form the photoelectric conversion layer. When semiconductor particles are calcined to form the photoelectric conversion layer, a sensitizing treatment applied to the semiconductor is preferably carried out after conducting calcination, and specifically, after conducting calcination, the sensitizing treatment is preferably conducted before water is adsorbed to the semiconductor. Next, a method by which semiconductor particles are calcined to form photoelectric conversion, layer 6 will be described.

The method by which semiconductor particles are calcined to form photoelectric conversion layer 6 is carried out via the following procedures. That is, (1) Preparation of coating solution containing semiconductor particles, (2) Calcination treatment and coating of coating solution containing semiconductor particles, and (3) Treatment of adsorbing sensitizing dye to semiconductor. Next, each of those described above will be explained.

(1) Preparation of Coating Solution Containing Semiconductor Particles

This step is a step in which semiconductor particles are charged into a commonly known solvent, and dispersed to prepare a coating solution. Semiconductor particles in the coating solution, for example, preferably have a content of 0.1-70% by weight, and more preferably have a content of 0.1-30% by weight. The semiconductor particles are preferably those each having a small particle diameter, and those having an average primary particle diameter of 1-5000 nm are preferably used, and those having an average primary particle diameter of 2-100 nm are more preferably used.

Further, a solvent in which semiconductor particles are dispersed is not specifically limited, as long as the solvent is capable of dispersing semiconductor particles without coagulating them, and examples thereof include water, a commonly known organic solvent, or a solution in which water and an organic solvent are mixed. Specific examples of the organic solvent include alcohols such as methanol, ethanol and so forth, ketones such as acetone, methylethyl ketone, acetylacetone and so forth, hydrocarbons such as n-hexane, cyclohexane and so forth, and so forth.

Further, a commonly known surfactant or viscosity adjusting agent is possible to be added into a coating solution, if desired, and typified specific examples of the viscosity adjusting agent include polyhydric alcohols such as polyethylene glycol and so forth.

(2) Calcination Treatment and Coating of Coating Solution Containing Semiconductor Particles

This step is a step by which a coating solution in which the foregoing semiconductor particles are dispersed in a solvent to form the coating solution is coated on a substrate on which the first electrode is formed, followed by drying to form a layer composed of semiconductor particles. Thus, semiconductor 5 is firmly attached onto the foregoing substrate in the form of a layer by conducting a calcination treatment in the air or inert gas. This semiconductor 5 formed in the form of a layer is one called a semiconductor layer. The layer composed of semiconductor particles formed on a substrate via coating has not only weak binding force with a support but also weak binding force of semiconductor particle-to-semiconductor particle, but when conducting a calcination treatment, binding force thereof with a support or binding force of semiconductor particle-to-semiconductor particle is improved, whereby a layer exhibiting durability together with strength results. The semiconductor formed via the calcination treatment preferably has a thickness of at least 10 nm, and more preferably has a thickness of 500 nm to 30 μm.

Further, the semiconductor layer forms a strong porous structure via the calcination treatment, and a photoelectric conversion efficiency is improved by making a hole transport material to be present in pores constituting a porous structure. In such a way, since the semiconductor layer having a porous structure has a larger actual surface area than a nominal surface area, various performances including a photoelectric conversion efficiency are to be very effectively improved. The semiconductor layer, for example, preferably has a porosity of 1-90% by volume, more preferably has a porosity of 10-80% by volume, and most preferably has a porosity of 20-70% by volume. Pores formed in the inside of a semiconductor layer exhibit through-holes with respect to the layer thickness direction, and the porosity is possible to be measured by a commonly known method. As a typical means to measure the porosity, for example, exemplified is a commercially available mercury porosimeter (Shimadzu Pore Analyzer 9220 type, manufactured by Shimadzu Corporation) or the like.

Temperature applied during the calcination treatment is preferably within a temperature range of less than 1000° C.; more preferably within a temperature range of 200-800° C.; and most preferably within a temperature range of 300-800° C. Incidentally, when forming a semiconductor layer having been subjected to a calcination treatment on a substrate made of a resin, the calcination treatment is not carried out necessarily at 200° C. or more, and firm adhesion of semiconductor particle-to-semiconductor particle as well as firm adhesion thereof with a substrate are possible by conducting a pressure-application treatment in place of the calcination treatment. Further, it is also possible to heat only a semiconductor layer without heating a substrate to conduct a calcination treatment.

Further, in order to conduct electron injection to a semiconductor layer with the after-mentioned sensitizing dye, the semiconductor layer having been formed via a calcination treatment is possible to be subjected to a plating treatment as a commonly known chemical or electrochemical method.

(3) Treatment of Adsorbing Sensitizing Dye to Semiconductor 5

A substrate above which a photoelectric conversion layer (a semiconductor layer) formed in the form of a layer is provided is immersed in a solution in which a sensitizing dye is dissolved to conduct a sensitizing dye for semiconductor 5. The total carrying amount of sensitizing dye 4 in photoelectric conversion layer 6 is preferably 0.01-100 mmol/m²; more preferably 0.1-50 mmol/m², and most preferably 0.5-20 mmol/m².

Any of a method using a single kind of sensitizing dye, and another method using plural kinds of sensitizing dyes in combination is possible for a sensitizing treatment, but in the case of a photoelectric conversion element for a solar cell, for example, a method using plural dyes each having a different absorption wavelength in combination is preferable in order to obtain a photoelectrically convertible wavelength range widely.

A solvent to dissolve a sensitizing dye is usable as a commonly known organic solvent, as long as the solvent neither dissolves semiconductors nor is a reactant, but dissolves the sensitizing dye. Examples of such a organic solvent include nitrile based solvents, alcohol based solvents, ketone based solvents, ether based solvents, halogenated hydrocarbon based solvents and so forth, as described below. These solvents are possible to be used singly, or in combination with plural kinds thereof.

(a) Examples of the nitrile based solvents include acetonitrile and so forth.

(b) Examples of the alcohol based solvents include methanol, ethanol, n-propanol and so forth.

(c) Examples of the ketone based solvents include acetone, methylethyl ketone, and so forth,

(d) Examples of the ether based solvents include diethyl ether, diisopropyl ether, tetrahydrofuran, 1,4-dioxane and so forth.

(e) Examples of the halogenated hydrocarbon based solvents include methylene chloride, 1,1,2-trichloroethane and so forth.

Among the above-described solvents, preferable are acetonitrile, a solvent in which acetonitrile and methanole are mixed, methanol, ethanol, acetone, methylethyl ketone, tetrahydrofuran and methylene chloride.

Time for immersion in a solution containing a sensitizing dye is, for example, preferably 3-48 hours, and more preferably 4-24 hours at 25° C. in order to penetrate the solution deeply into the semiconductor layer to sufficiently accelerate adsorption to semiconductors and to sufficiently sensitize the semiconductors. Further, the solution is possible to be heated as long as the contained sensitizing dye is not degraded, and solution temperature can be designed to be set to 25-80° C.

Photoelectric conversion layer 6 is possible to be prepared via the following procedures.

[3] Formation of Hole Transport Layer

In the present invention, it is possible to form hole transport layer 7 containing a conductive polymer as a hole transport material via the foregoing method, and hole tansport layer 7 which has been formed is formed in such a way that it is penetrated into photoelectric conversion layer 6.

[4] Formation of the Second Electrode

The second electrode is formed on the upper surface of a hole transport layer. The second electrode is possible to be formed with the second electrode material made of, for example, gold or the like by a commonly known method such as an evaporation method, a sputtering method, a printing method or the like.

A dye-sensitized solar cell of the present invention is possible to be formed via the above-described steps.

### EXAMPLE

Next, the present invention will be specifically described in detail referring to Examples, but the present invention is not limited only to the following Examples. Incidentally, “parts” in the following descriptions represent “parts by weight”.

1.Preparation of “dye-sensitized solar cells 1-20”

Preparation of “dye-sensitized solar cell 1”

“Dye-sensitized solar cell 1” having a structure shown in FIG. 1 was prepared via the following procedures.

(1) Preparation of Substrate

Employing a commercially available 30 mm by 35 mm substrate having a thickness of 2.5 mm, the substrate was immersed in washing liquid at 85° C. as a solution in which a sulfuric acid and hydrogen peroxide water were mixed to conduct a washing treatment, whereby the surface of the substrate was cleansed.

(2) Formation of the First Electrode and Barrier Layer

Employing a commonly known evaporation system film-forming apparatus, the first electrode of 30 mm by 35 mm having a thickness of 1 μm and having a sheet resistance of 20 Ω/□, which was made of FTO (fluorine-doped tin oxide) was formed on the following soda glass substrate. A solution obtained by dissolving 1.2 mL of tetrakisisopropoxy titanium, and 0.8 mL of acetylacetone in 18 mL of ethanol was dropped onto a substrate on which the first electrode was formed to form a film by a spin coating method, followed by heating at 450 ° C. for 8 minutes, and then, a barrier layer made of titanium oxide, having a thickness of 40 nm was formed on the first electrode.

(3) Formation of Photoelectric Conversion Layer

Next a photoelectric conversion layer made of titanium oxide was formed on the upper surface of the foregoing barrier layer provided on the first electrode as an FTO thin film. That is, an anatase type titanium dioxide {average primary particle diameter: 18 nm (microscopic observation average), and ethyl cellulose dispersion} was coated on the foregoing soda glass substrate on which the first electrode and the barrier layer as described above were formed by a screen printing method so as to make the coating area to become 25 mm². After coating, a calcination treatment was carried out at 200° C. for 10 minutes and at 500° C. for 15 minutes to form a titanium dioxide thin film having a thickness of 2.5 μm. The titanium dioxide thin film had a porous structure possessing pores.

Next dye 1 having the following structure was dissolved in a mixed solvent of acetonitrile: t-butyl alcohol=1:1 to form 5×10⁻⁴ mol/L of a solution for a sensitizing dye.

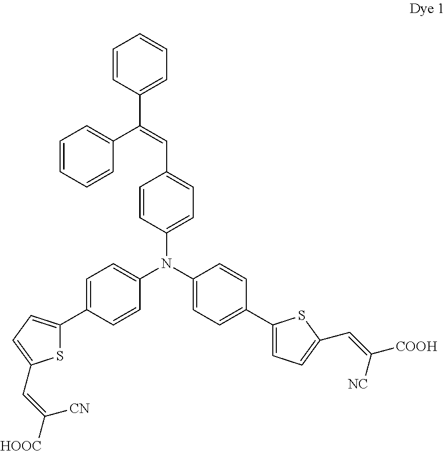 [SMILES: N#C/C(=C\c1ccc(-c2ccc(N(c3ccc(C=C(c4ccccc4)c4ccccc4)cc3)c3ccc(-c4ccc(/C=C(\C#N)C(=O)O)s4)cc3)cc2)s1)C(=O)O]

The foregoing glass substrate on which the above-described titanium dioxide was coated followed by calcination was immersed in the above-described solution for 3 hours to conduct a sensitizing treatment via adsorption of the above-described dye. In this way, a photoelectric conversion layer was formed.

(4) Formation of Hole Transport Layer

A glass substrate on which the foregoing photoelectric conversion layer was formed was immersed in the following electropolymerization solution to conduct electropolymerization, resulting in formation of a hole transport layer.

The above-described immersion was carried out in a solution of acetonitrile/propylene carbonate=1/9 formed from 0.01 mol/L of a compound M1 represented by Formula (1) and 0.1 mol/L of dopant Li [(CF₃SO₂)₂N] to conduct electropolymerization, whereby a hole transport layer containing a conductive polymer insoluble in a solvent was formed on the foregoing photoelectric conversion layer.

The foregoing first electrode as a working electrode, platinum wire as a counter electrode, and Ag/Ag⁺(0.01 mol of AgNO₃) as a reference electrode were employed for the above-described electropolymerization, and hold voltage was set to −0.16 V. Then, the voltage is maintained for 30 minutes while making light exposure from the direction of a photoelectric conversion layer (a Xenon lamp as a light source, a light intensity of 20 mW/cm², and a wavelength of 430 nm or less to be cut off).

After forming a hole transport layer in the above-described procedures, the foregoing glass substrate was washed with acetonitrile, and subjected to a drying treatment. Thereafter, it was immersed in an acetonitrile containing 1.5×10⁻² mol/L of Li [(CF₃SO₂)₂N], and 5×10⁻² mol/L of t-butyl pyridine for 10 minutes, followed by drying to prepare a hole transport layer,

(5) Formation of the Second Electrode

Next, gold was evaporated onto the foregoing hole transport layer by a vacuum evaporation method so as to give a thickness of 60 nm to form the second electrode. Thus, dye-sensitized solar cell 1 was prepared.

Preparation of “dye-sensitized solar cells 2-19”

“dye-sensitized solar cells 2-19” were prepared similarly to the procedure in preparation of the foregoing “dye-sensitized solar cell 1”, except that compound “M1” for an electropolymerization solution used for forming a hole transport layer, represented by Formula (1) and kind, concentration, solvent and so forth were replaced by compounds, dopants and solvents shown in the following Table 1.

Preparation of “dye-sensitized solar cell”

(1) Preparation of Substrate

Employing a commercially available 30 mm by 35 mm substrate having a thickness of 2.5 mm, the substrate was immersed in washing liquid at 85° C. as a solution in which a sulfuric acid and hydrogen peroxide water were mixed to conduct a washing treatment, whereby the surface of the substrate was cleansed.

(2) Formation of the First Electrode and Barrier Layer

Employing a commonly known evaporation system film-forming apparatus, the first electrode of 30 mm by 35 mm having a thickness of 1 μm and having a sheet resistance of 20 Ω/□, which was made of FTO (fluorine-doped tin oxide) was formed on the following soda glass substrate. A solution obtained by dissolving 1.2 mL of tetrakisisopropoxy titanium and 0.8 mL of acetylacetone in 18 mL of ethanol was dropped onto a substrate on which the first electrode was formed to form a film by a spin coating method, followed by heating at 450° C. for 8 minutes, and then, a barrier layer made of titanium oxide, having a thickness of 40 nm was formed on the first electrode.

(3) Formation of Photoelectric Conversion Layer

Next, a photoelectric conversion layer made of titanium oxide was formed on the upper surface of the foregoing barrier layer provided on the first electrode as an FTO thin film. That is, an anatase type titanium dioxide {average primary particle diameter; 18 nm (microscopic observation average), and ethyl cellulose dispersion} was coated on the foregoing soda glass substrate on which the first electrode and the barrier layer as described above were formed by a screen printing method so as to make the coating area to become 25 mm². After coating, a calcination treatment was carried out at 200° C. for 10 minutes and at 500° C. for 15 minutes to form a titanium dioxide thin film having a thickness of 2.5 μm. The titanium dioxide thin film had a porous structure possessing pores.

Next, Z907 Dye (produced by SOLARONIX SA) represented by the following structure was dissolved in a mixed solvent of acetonitrile: t-butyl alcohol=1:1 to form 3×10⁻⁴ mol/L of a solution for a sensitizing dye.

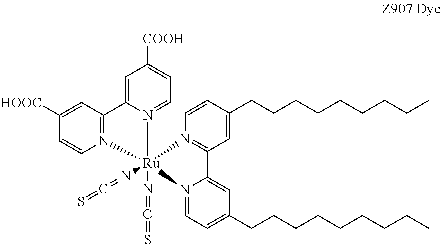

The foregoing glass substrate on which the above-described titanium dioxide was coated followed by calcination was immersed in the above-described solution for 18 hours to conduct a sensitizing treatment via adsorption of the above-described dye. In this way, a photoelectric conversion layer was formed.

(4) Formation of Hole Transport Layer

A glass substrate on which the foregoing photoelectric conversion layer was formed was immersed in an acetonitrile solution formed from 0.01 mol/L of M1 and 0.1 mol/L of Li [(CF₃SO₂)₂N] to conduct electropolymerization, whereby a hole transport layer containing a conductive polymer insoluble in a solvent was formed on the foregoing photoelectric conversion layer.

The foregoing first electrode as a working electrode, platinum wire as a counter electrode, and Ag/Ag⁺(0.01 mol of AgNO₃) as a reference electrode were employed for the above-described electropolymerization, and hold voltage was set to −0.16 V. Then, the voltage is maintained for 30 minutes while making light exposure from the direction of a photoelectric conversion layer (a Xenon lamp as a light source, a light intensity of 20 mW/cm², and a wavelength of 520 nm or less to be cut off).

After forming a hole transport layer in the above-described procedures, the foregoing glass substrate was washed with acetonitrile, and subjected to a drying treatment. Thereafter, a 1-butyl-3-methylimidazolium bis-trifluoromethanesulfonylimide (BMIIm-TFSI) solution containing 0.2 mol/L of Li[(CF₃SO₂)₂N] and 0.2 mol/L of t-butyl pyridine was dropped onto a hole transport layer, and the resulting was sandwiched by FTO electrodes each having been subjected to evaporation of gold to prepare “dye-sensitized solar cell 20”.

TABLE 1

| | Composition of electropolymerization solution for hole transport layer | | | | | | | | |
|---|---|---|---|---|---|---|---|---|---|
| Dye- | | | | Solvent | Dielectric | | Dopant | | |
| Sensitized | Compound | Solvent 1 | Solvent 2 | ratio | constant (ε) | Kinds | con- | Ionization | |
| solar cell | represented | [Dielectric | [Dielectric | (Solvent 1/ | of mixed | of | centration | potential | Re- |
| No. | Formula (1) | constant (ε)] | constant (ε)] | Solvent 2) | solvent | dopant | (mol/L) | (eV) | marks |
| 1 | M1 | Propylene carbonate (64.4) | Acetonitrile (37.5) | 1/9 | 40 | *1 | 0.1 | 5 | Inv. |
| 2 | M1 | Propylene carbonate (64.4) | Acetonitrile (37.5) | 5/5 | 51 | *1 | 0.05 | 5.2 | Inv. |
| 3 | M4 | Propylene carbonate (64.4) | Acetonitrile (37.5) | 7/3 | 56 | *1 | 0.1 | 5.3 | Inv. |
| 4 | M12 | Propylene carbonate (64.4) | Acetonitrile (37.5) | 8/2 | 59 | *2 | 0.1 | 5.5 | Inv. |
| 5 | M2 | Ethylene carbonate (89.6) | Acetonitrile (37.5) | 1/9 | 43 | *1 | 0.05 | 5.1 | Inv. |
| 6 | M6 | Ethylene carbonate (89.6) | Acetonitrile (37.5) | 2/8 | 48 | *1 | 0.05 | 5.1 | Inv. |
| 7 | M7 | Ethylene carbonate (89.6) | Acetonitrile (37.5) | 4/6 | 58 | *2 | 0.25 | 5.4 | Inv. |
| 8 | M7 | Propylene carbonate (64.4) | γ-butyrolactone (39.0) | 2/8 | 44 | *1 | 0.1 | 5 | Inv. |
| 9 | M8 | Propylene carbonate (64.4) | γ-butyrolactone (39.0) | 5/5 | 52 | *1 | 0.05 | 5.3 | Inv. |
| 10 | M6 | Propylene carbonate (64.4) | γ-butyrolactone (39.0) | 7/3 | 57 | *1 | 0.05 | 5.4 | Inv. |
| 11 | M13 | Ethylene carbonate (89.6) | γ-butyrolactone (39.0) | 3/7 | 54 | *1 | 0.1 | 5.3 | Inv. |
| 12 | M15 | Propylene carbonate (64.4) | Acetone (20.7) | 5/5 | 43 | *1 | 0.35 | 5.1 | Inv. |
| 13 | M16 | Ethylene carbonate (89.6) | Acetone (20.7) | 5/5 | 55 | *3 | 0.1 | 5.2 | Inv. |
| 14 | M15 | Propylene carbonate (64.4) | Cyclohexane (18.3) | 5/5 | 41 | *1 | 0.4 | 5.1 | Inv. |
| 15 | M13 | Ethylene carbonate (89.6) | Cyclohexane (18.3) | 5/5 | 53 | *1 | 0.1 | 5.3 | Inv. |
| 16 | M1 | Propylene carbonate (64.4) | — | 10/0 | 64 | *1 | 0.1 | 5.6 | Comp. |
| 17 | M1 | — | Acetonitrile (37.5) | 0/10 | 38 | *1 | 0.1 | 4.9 | Comp. |
| 18 | M1 | Propylene carbonate (64.4) | Acetonitrile (37.5) | 1/9 | 40 | *1 | 0.02 | 4.9 | Comp. |
| 19 | M1 | Propylene carbonate (64.4) | Acetonitrile (37.5) | 8/2 | 59 | *1 | 0.55 | 5.6 | Comp. |
| 20 | M1 | — | Acetonitrile (37.5) | 0/10 | 38 | *1 | 0.1 | 4.9 | Comp. |

*1: Li[(CF₃SO₂)₂N],
*2: LiClO₄,
*3: LiCF₃SO₃,
Inv.: Present invention,
Comp.: Comparative example

2. Experiment for Evaluation

As to “dye-sensitized solar cells 1-20” prepared by the above-described procedures, photoelectric conversion efficiency was evaluated as described below.

Photoelectric conversion efficiency η of each of the dye-sensitized solar cells was measured by the following procedures, and the measured result was calculated. Each of the dye-sensitized solar cells was exposed to pseudo solar light at an exposure intensity of 100 mW/cm² produced by a commercially available solar simulator (WXS-85-H, manufactured by WACOM ELECTRIC Co.. Ltd.) under the room temperature environment (at 20° C.). The foregoing pseudo solar light is one formed by making Xenon lamp light to pass through an AM filter (AM 1.5) employing a solar simulator.

Herein, a current-voltage characteristic of each of dye-sensitized solar cells is measured during exposure to the foregoing pseudo solar light, employing a commercially available I-V tester, and short-circuit current value Jsc and open-circuit voltage Voc, and form factor FF obtained from a current-voltage characteristic graph are determined via calculation. These values are substituted into the after-mentioned calculus equation to determine photoelectric conversion efficiency η.

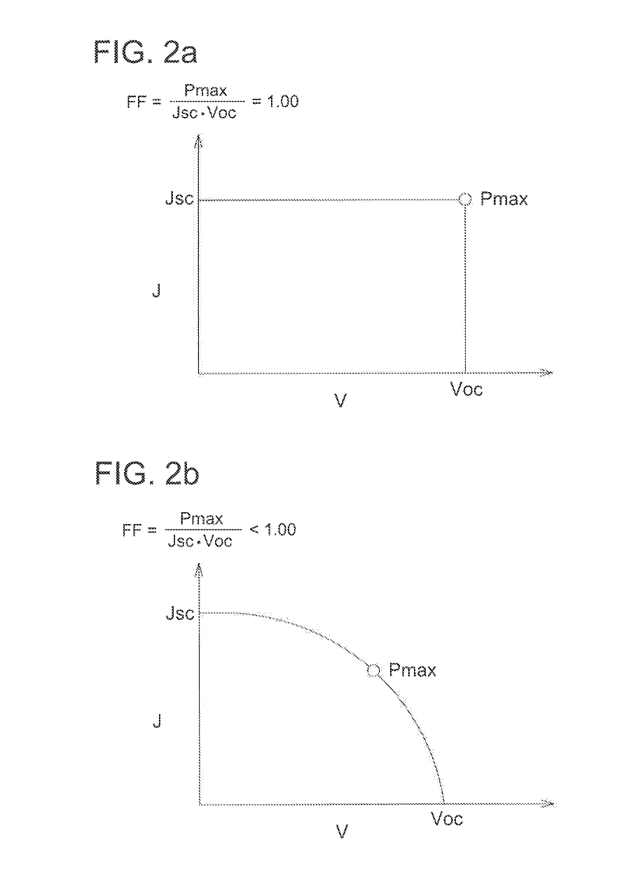

In addition, the above-described “open-circuit voltage Voc” means a voltage value at a time when no current flows by applying a voltage load to a dye-sensitized solar cell, and the above-described “short-circuit current value Jsc” means a current value flowing at the time of a state where no voltage load is applied to a dye-sensitized solar cell. Further, the above-described “form factor FF” is one in which the trajectory shown in a current-voltage characteristic graph is represented by the numerical value obtained during measurement of the after-mentioned photoelectric conversion efficiency, and is a value obtained by dividing exposure intensity Pmax by the product of short-circuit current value Jsc and open-circuit voltage Voc. FIGS. 2a and 2b show trajectories of current-voltage characteristic graphs in the case of form factor FF=1.00, and also in the case of form factor FF<1.00.

Further, photoelectric conversion efficiency η is determined via calculation by the following equation. That is, when exposure intensity, short-circuit current of each dye-sensitized solar cell open-circuit voltage of each dye-sensitized solar cell, and form factor of each dye-sensitized solar cell are designated as Pmax, Jsc (mA/cm²), Voc (V) and FF, respectively, photoelectric conversion efficiency η (%) is calculated by the following equation. That is, η (%)=[(Jsc×Voc×FF)/Pmax]×100

In addition, in the present evaluations, given is exposure thereof to pseudo solar light at an exposure intensity Pmax of 100 mW/cm² employing the foregoing solar simulator.

Results obtained as described above are shown in the following Table 2.

TABLE 2

| | | Short- | | |
|---|---|---|---|---|
| Dye- | Open- | circuit | Photoelectric | |
| sensitized | circuit | current | conversion | |
| solar cell | voltage | density | efficiency | |
| No. | (mV) | (mA/cm²) | (%) | Remarks |
| 1 | 1011 | 6.02 | 4.26 | Present invention |
| 2 | 1927 | 6.32 | 4.61 | Present invention |
| 3 | 1042 | 5.99 | 4.43 | Present invention |
| 4 | 1052 | 5.75 | 4.29 | Present invention |
| 5 | 1015 | 6.27 | 4.51 | Present invention |
| 6 | 1019 | 6.42 | 4.64 | Present invention |
| 7 | 1038 | 5.89 | 4.34 | Present invention |
| 8 | 1008 | 6.72 | 4.61 | Present invention |
| 9 | 1035 | 6.01 | 4.22 | Present invention |
| 10 | 1045 | 5.87 | 4.17 | Present invention |
| 11 | 1033 | 5.97 | 4.25 | Present invention |
| 12 | 1022 | 5.76 | 4.06 | Present invention |
| 13 | 1009 | 6.11 | 4.25 | Present invention |
| 14 | 1013 | 6.09 | 4.26 | Present invention |
| 15 | 1031 | 5.88 | 4.18 | Present invention |
| 16 | 1068 | 4.87 | 3.38 | Comparative |
| | | | | example |
| 17 | 867 | 6.28 | 3.43 | Comparative |
| | | | | example |
| 18 | 891 | 6.03 | 3.33 | Comparative |
| | | | | example |
| 19 | 1064 | 4.79 | 3.11 | Comparative |
| | | | | example |
| 20 | 750 | 4.30 | 2.35 | Comparative |
| | | | | example |

As shown in Table 2, when a conductive polymer having an ionization potential of 5.0-5.5 eV is used as a hole transport material for a hole transport layer, each of dye-sensitized solar cells 1-15 can obtain high open-circuit voltage, high photoelectric conversion efficiency and so forth, and can improve the conversion efficiency in comparison to dye-sensitized solar cells 16-20 as Comparative examples.

### EFFECT OF THE INVENTION

In the present invention, as to a dye-sensitized solar cell in which a conductive polymer is contained in a hole transport layer, a high photoelectric conversion efficiency was able to be obtained by controlling a hole transport material having a specific structure and ionization potential of a hole transport layer to fall within the predetermined range.

What is claimed is:

1. A dye-sensitized solar cell comprising a first electrode and provided thereon, a photoelectric conversion layer comprising a semiconductor and a sensitizing dye, a hole transport layer comprising a solid state hole transport material and a second electrode in this order,
wherein the solid state hole transport material contained in the hole transport layer comprises a conductive polymer formed by polymerizing a compound having a structure represented by the following Formula (1), and the hole transport layer has an ionization potential of 5.0-5.5 eV: 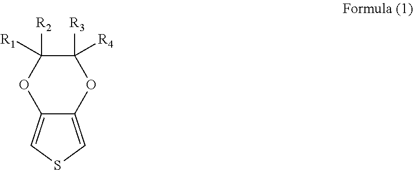
where each of R₁, R₂, R₃ and R₄ represents a hydrogen atom, a halogen atom, an alkyl group, a cycloalkyl group, an alkoxy group, an aryl group, or an alkyl group comprising an oxyethylene group, and R₁, R₂, R₃ and R₄ may be identical to each other, or may be different from each other.

2. The dye-sensitized solar cell of claim 1,
wherein at least one of R₁, R₂, R₃ and R₄ in the compound having a structure represented by Formula (1) comprises an alkyl group having 3-14 carbon atoms, or an alkyl group comprising an oxyethylene group.

3. The dye-sensitized solar cell of claim 1,
wherein the hole transport layer is formed during electropolymerization.

4. The dye-sensitized solar cell of claim 3,
wherein a solvent used during the eledropolymerization is a mixed solvent comprising a solvent having a dielectric constant of 50 or more.

5. The dye-sensitized solar cell of claim 4,
wherein an electrolytic solution used during the electropolymerization comprises a compound represented by Formula (1) and a supporting electrolyte, and the supporting electrolyte has 2.5-50 times larger molar concentration than that of the compound represented by Formula (1).
